(19) United States
(12) Patent Application Publication
(10) Pub. No.: US 2026/0037682 A1
(43) Pub. Date: Feb. 5, 2026

(54) LOGISTICS TRANSPORTATION DIGITAL TWIN SYSTEM FOR MODULAR CLEANROOM

(71) Applicant: LOCUS CELL CO., LTD, New Taipei City (TW)

(72) Inventors: Heng-Yu Liu, New Taipei City (TW); Hui-Ling Chen, New Taipei City (TW); Wei-Ting Lin, New Taipei City (TW)

(21) Appl. No.: 19/267,683

(22) Filed: Jul. 14, 2025

Related U.S. Application Data
(60) Provisional application No. 63/677,142, filed on Jul. 30, 2024.

(51) Int. Cl. G06F 30/13; G06F 30/15

(52) U.S. Cl. CPC G06F 30/13; G06F 30/15

(57) ABSTRACT

A logistics transportation digital twin system for a modular cleanroom comprises: a three-dimensional model computation module configured to construct three-dimensional models of the modular cleanroom and an automated guided vehicle (AGV); a perception data processing module comprising a plurality of cleanrooms, and each cleanroom comprising a plurality of partition panels configured for rapid assembly to form internal spaces and external areas; a perception data processing module configured to sense cleanroom parameters of the modular cleanroom and operational parameters of the AGV, so as to generate corresponding cleanroom perception data and operational perception data; a digital twin module configured to perform simulation computations on the cleanroom perception data and operational perception data corresponding to the three-dimensional models, so as to generate a three-dimensional simulation result; and a visual display module configured to visually present the three-dimensional simulation result.

The present application is based on, and claims priority from, America provisional patent application number U.S. 63/677,142 filed on 2024 Jul. 30 and the disclosure of which is hereby incorporated by reference herein in its entirety.

### BACKGROUND OF THE INVENTION

### Field of the Invention

The present invention relates to a digital twin system, and in particular toa logistics transportation digital twin system for a modular cleanroom.

### Description of the Prior Art

In modern manufacturing industries, cleanroom technology plays a critical role in sectors such as semiconductors, pharmaceuticals, biotechnology, and food production by maintaining highly clean production environments to ensure product quality and safety. Especially in cell factories, the manufacturing process of cell-based products requires extremely stringent sterility. Any microbial contamination may result in the disposal of the entire batch of products and adversely affect therapeutic outcomes. Due to the characteristics of cell-based products, each production run must focus on one specific product to avoid cross-contamination. As the industry's demand for flexible manufacturing and customized production requirements increases, traditional cleanroom designs and logistics systems face significant challenges when operating multiple production lines simultaneously, comprising:
1. Lack of flexibility in fixed designs
   Traditional cleanrooms use fixed partition panels, making it difficult to quickly adjust layouts according to varying product requirements. During production schedule changes or yearly maintenance periods, the space cannot be reconfigured flexibly, resulting in decreased production efficiency.
2. Difficulty in multi-cleanroom collaboration
   Under the CDMO (Contract Development and Manufacturing Organization) model, cell factories must operate multiple cleanrooms simultaneously, with each cleanroom possibly serving different customer needs. Existing technologies lack effective digital twin simulation and prediction capabilities, making it difficult to evaluate the collaborative efficiency and logistics bottlenecks among multiple cleanrooms.
3. High risk of cross-contamination
   When multiple cleanrooms are operated concurrently, materials and equipment are usually transported by automated guided vehicles (AGVs). As AGVs move among different cleanrooms, they may carry microbial contaminants, which could affect production yield and product quality.
4. Low logistics transportation efficiency
   Current logistics systems often are operated on fixed routes and lack real-time scheduling and optimization based on digital twin technology. When multiple production lines run simultaneously, AGV paths are prone to overlap and congestion, causing transportation delays.
5. Lack of real-time monitoring and control mechanisms
   Many systems still rely on manual periodic inspections to monitor cleanroom conditions, making it difficult to instantly detect and control air quality issues, logistics flow, and equipment status. As a result, contamination sources are difficult to be identified and controlled in a timely manner.

To address the aforementioned issues, prior art has attempted to integrate cleanroom planning with digital twin technology. However, existing solutions still suffer from several limitations:
1. Production affected by time-consuming decontamination
   After each production batch, a full-scale decontamination process is required to ensure a sterile environment. This process is time-consuming and energy-intensive, which restricts production scheduling and limits the flexibility to respond to production demands.
2. Digital twin technology limited to a single cleanroom
   Although current digital twin technologies can monitor equipment status in real time, they are mostly confined to one single cleanroom and lack the capability to simulate and analyze multi-cleanroom operations.
3. Insufficient simulation dimensions
   When multiple cleanrooms are operated simultaneously, factors such as airflow dynamics, logistics paths, and equipment operation must be considered all together. Existing systems struggle to simulate and optimize under these multidimensional conditions.
4. Inadequate cross-cleanroom logistics management
   Traditional AGV systems do not fully accommodate the logistics needs across multiple cleanrooms, leading to route overlaps and transportation bottlenecks that reduce overall production efficiency.
5. Lack of digitalization in decontamination processes
   In conventional technologies, decontamination is still manually performed and recorded, lacking digital twin-based predictions of cleaning duration and resource allocation, which increases the complexity of production management.

Therefore, it is necessary to provide a system capable of rapidly adjusting factory scheduling and logistics configurations according to production line demands, while simultaneously preventing cross-contamination between raw materials and contaminants, and effectively managing production challenges caused by yearly maintenance of equipment, in order to ensure production efficiency and product quality.

### SUMMARY OF THE INVENTION

In view of this, the present invention provides a logistics transportation digital twin system for a modular cleanroom, so as to address the aforementioned conventional problems.

The present invention provides a logistics transportation digital twin system for a modular cleanroom. The system comprises a three-dimensional model computation module, a perception data processing module, a digital twin module and a visual display module. The three-dimensional model computation module is configured to construct a three-dimensional model of the modular cleanroom and an automated guided vehicle (AGV). Wherein, the modular cleanroom comprises a plurality of cleanrooms, and each of the cleanroom comprises a plurality of partition panels configured for rapid assembly to form an internal space and an external area.

The perception data processing module is coupled to the three-dimensional model computation module. The perception data processing module is configured to perceive a cleanroom parameter of the modular cleanroom to generate a cleanroom perception data, and to perceive an operational parameter of the automated guided vehicle to generate an operational perception data. The digital twin module is coupled to the three-dimensional model computation module and the perception data processing module. The digital twin module is configured to perform simulation computation on the cleanroom perception data and the operational perception data with respect to the three-dimensional model to generate a three-dimensional simulation result. The visual display module is coupled to the digital twin module, and is configured to visually present the three-dimensional simulation result.

Wherein, the logistics transportation digital twin system for the modular cleanroom is further integrated with a manufacturing execution system configured to monitor, track, and record a production process, and to collect and aggregate the cleanroom perception data and the operational perception data in real time, thereby managing and controlling the production process effectively.

Wherein, the logistics transportation digital twin system for the modular cleanroom is applied to a cell factory. The cell factory is a cell factory operating under a contract development and manufacturing organization (CDMO) model. Each of the partition panels is a movable panel. The internal space of each of the cleanrooms is a sealed space maintained under positive pressure and laminar flow to achieve a predefined cleanliness level.

Wherein, when the cell factory schedules a yearly maintenance, a repair and maintenance, or a production process, the cleanroom that is designated from the modular cleanrooms is reconfigured by quickly disassembling each of the movable partition panels based on the yearly maintenance, the repair and maintenance, or the production schedule, so as to comply with the yearly maintenance, the repair and maintenance, or the production schedule.

Wherein, the perception data processing module further comprises at least one sensor. The at least one sensor is configured to detect an operational state of the modular cleanroom and the automated guided vehicle. The at least one sensor is disposed on one of the partition panels and positioned at a boundary between the internal space and the external area, so as to monitor a cleanliness level of the internal space, a logistics activity in the external area, and an operational trajectory of the automated guided vehicle in real time.

Wherein, the digital twin module further comprises a data computation and analysis unit. The data computation and analysis unit is configured to analyze the cleanroom perception data and the operational perception data, and to predict a transportation behavior of the automated guided vehicle in the modular cleanroom via a machine learning model, so as to generate an optimized transportation path for the automated guided vehicle.

Wherein, the digital twin module further comprises a cleanroom operation simulation unit. The cleanroom operation simulation unit is configured to simulate an airflow dynamic and a contamination diffusion path of the internal space of the cleanrooms, and a transportation route of the automated guided vehicle in the external area of the cleanrooms, and to optimize the transportation route through a machine learning model to provide an optimized transportation path.

Wherein, the internal space is suitable for a high-cleanliness production environment, and the external area is suitable for a material transportation zone and an equipment storage zone.

Wherein, the automated guided vehicle is disposed in the external area of the modular cleanroom to deliver a material or an equipment into the internal space through a docking window. The automated guided vehicle further comprises a body and an inner cavity. The inner cavity is disposed within the body. The inner cavity comprises a connector corresponding to the docking window for delivering an object into the internal space through the docking window.

Wherein, the docking window further comprises a first docking window and a second docking window. The object further comprises a first object and a second object. The automated guided vehicle is configured to deliver the first object into the internal space through the first docking window, and to deliver the second object into the external area through the second docking window. Wherein, a geometry of the first docking window is different from a geometry of the second docking window.

Wherein, the cleanroom parameter further comprises one or more of a personnel parameter, an equipment parameter, a material parameter, and an environmental parameter.

Wherein, the three-dimensional model computation module, the perception data processing module, the digital twin module, and the visual display module are further configured to synchronize data via a wireless communication method or a wired communication method to provide real-time operational monitoring.

In summary, the present invention provides a logistics transportation digital twin system for a modular cleanroom, which comprehensively addresses the issues in the prior art such as rigid production scheduling, difficulties in multi-cleanroom collaboration, low logistics transportation efficiency, and insufficient monitoring, thereby fully demonstrating its technical advantages and innovativeness. The present invention combines modular cleanroom design with digital twin technology to rapidly adjust spatial configurations based on production line demands, significantly enhancing the flexibility of production scheduling and the efficiency of space utilization, thereby making factory layouts more adaptable and responsive. The system features built-in digital twin simulation functions for multiple cleanrooms, allowing real-time analysis of collaborative performance and logistics bottlenecks among cleanrooms, thereby improving the efficiency of parallel production lines and meeting the demands of high-requirement manufacturing models such as CDMO. Furthermore, through intelligent AGV scheduling and digital twin-based logistics simulation, the system can optimize logistics routes in real time and intelligently avoid AGV path overlaps and congestion issues. This significantly enhances overall logistics dispatch efficiency and enables a highly efficient and streamlined production process. In addition, the invention overcomes the limitations of conventional technologies that only monitor a single production area by integrating multi-cleanroom collaboration simulation with real-time logistics scheduling, thereby achieving full-process intelligent management from production to logistics. This approach not only effectively improves production efficiency, but also significantly reduces the risk of cross-contamination and production interruptions caused by logistics bottlenecks, thereby ensuring the stability and reliability of the manufacturing process. Finally, the present invention, leveraging real-time data analysis and intelligent scheduling capabilities, can rapidly respond to changing production demands and achieve decision optimization through data-driven approaches, thereby comprehensively enhancing the reliability, flexibility, and operational efficiency of the cleanroom production environment.

### BRIEF DESCRIPTION OF THE APPENDED DRAWINGS

Some of the embodiments will be described in detail, with reference to the following figures, wherein like designations denote like members, wherein:

FIG. 1 shows afunctional block diagram of a logistics transportation digital twin system for a modular cleanroom of one embodiment of the present invention.

FIG. 2 shows a functional block diagram of a logistics transportation digital twin system for a modular cleanroom of one embodiment of the present invention.

FIG. 3 shows a functional block diagram of a logistics transportation digital twin system for a modular cleanroom of one embodiment of the present invention.

### DETAILED DESCRIPTION OF THE INVENTION

In order to make the advantages, spirit and features of the present invention easier and clearer, it will be detailed and discussed in the following with reference to the embodiments and the accompanying drawings. It is worth noting that the specific embodiments are merely representatives of the embodiments of the present invention. The specific methods, devices, conditions, and materials described herein are not intended to limit the scope of the invention or the embodiments corresponding thereto. Additionally, the components illustrated in the drawings are intended only to indicate relative positions and are not necessarily drawn to scale. The step numbers used in the present invention are for distinguishing between steps only and do not imply any particular execution order unless otherwise stated.

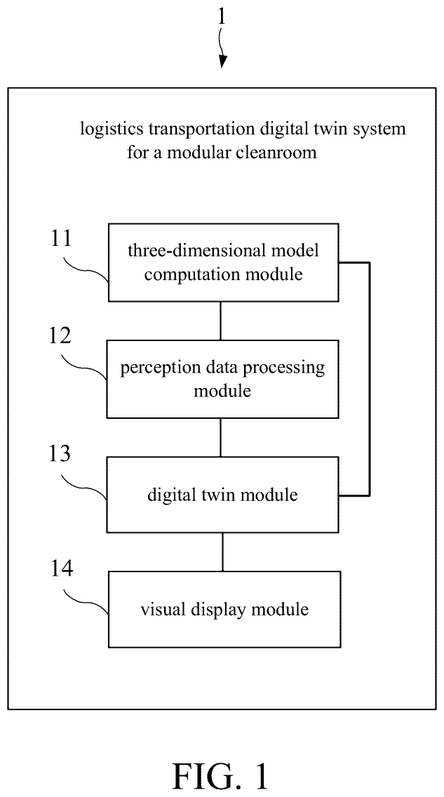

Please refer to FIG. 1, FIG. 1 shows afunctional block diagram of a logistics transportation digital twin system for a modular cleanroom 1 of one embodiment of the present invention. This embodiment provides a logistics transportation digital twin system for a modular cleanroom 1, which comprises a three-dimensional model computation module 11, a perception data processing module 12, a digital twin module 13, and a visual display module 14. The three-dimensional model computation module 11 is configured to construct a three-dimensional model of the modular cleanroom (not shown) and an automated guided vehicle (AVG) (not shown). In this embodiment, the modular cleanroom comprises a plurality of cleanrooms, and each cleanroom includes a plurality of partition panels configured for rapid assembly to form an internal space and an external area. The perception data processing module 12 is coupled to the three-dimensional model computation module 11. The perception data processing module 12 is configured to perceive a cleanroom parameter of the modular cleanroom and an operational parameter of the automated guided vehicle, so as to generate corresponding cleanroom perception data and operational perception data. In this embodiment, the cleanroom parameter may further comprise one or more of a personnel parameter, an equipment parameter, a material parameter, and an environmental parameter. For example, the environmental parameter may include data such as temperature, humidity, airflow, and particle concentration, to reflect the real-time environmental condition of the cleanroom. However, in practical applications, the types and quantities of cleanroom parameters are not limited to the above examples and may be expanded or configured based on user needs, production line requirements, or application scenarios. The digital twin module 13 is coupled to both of the three-dimensional model computation module 11 and the perception data processing module 12. It is configured to map the obtained cleanroom perception data and operational perception data to the three-dimensional models for simulation computation, so as to generate three-dimensional simulation results. This enables the simulation of logistics transportation and human-machine interaction scenarios within the actual space, allowing for predictive analysis and anomaly alerts. The visual display module 14 is coupled to the digital twin module 13 and is configured to present the above simulation results of the three-dimensional computations in a graphical user interface in real-time, allowing users to observe the transportation status, personnel movement paths, equipment configurations, and environmental changes within the modular cleanroom through the display interface.

In this embodiment, the three-dimensional model computation module 11, the perception data processing module 12, the digital twin module 13, and the visual display module 14 are further configured to synchronize data via wireless communication (such as Wi-Fi, Zigbee, or 5G) or wired communication (such as Ethernet or RS-485) to provide real-time operational monitoring capabilities, and further support decision analysis and operational optimization. In practical applications, the three-dimensional model computation module 11, the perception data processing module 12, the digital twin module 13, and the visual display module 14 of the logistics transportation digital twin system for a modular cleanroom 1 may be integrated into a computer system, a central processing unit of a cloud system, or an integrated chip, so as to facilitate system deployment and rapid implementation across multiple sites.

Furthermore, in this embodiment, the logistics transportation digital twin system for the modular cleanroom may be further connected to a Manufacturing Execution System (MES), configured to monitor, track, and record production processes, and to collect and integrate various production data in real time, including the cleanroom perception data and the operational perception data, so as to effectively manage and control the overall production flow. In addition, through data synchronization and simulation interaction with the digital twin module 13, various production-related data can be further integrated and processed, including but not limited to work order progress, equipment (machine) operation status, quality inspection records, personnel scheduling information, material usage information, and environmental monitoring parameters. This enables real-time monitoring and intelligent decision-making for the entire manufacturing process. With the system's capabilities in data integration and visual simulation, not only can the overall process transparency and responsiveness be improved, but potential production bottlenecks and abnormal conditions can also be identified in real time, thereby enhancing the system's early warning capabilities and decision-making efficiency, and ultimately achieving a data-driven smart manufacturing objective.

In this embodiment, the logistics transportation digital twin system for the modular cleanroom 1 may be applied to a cell factory, which may further be a Contract Development and Manufacturing Organization (CDMO) type cell factory. Each of the partition panels may be a movable panel. The material of the partition panels may include stainless steel, aluminum alloy, high-pressure laminate (HPL), or other composite materials. Each partition panel may be quickly assembled or disassembled with other panels via connecting components such as sealing strips, latches, or joint clips. The internal space of each cleanroom may be a sealed space, which is maintained under positive pressure and laminar flow to achieve a predefined cleanliness level. The predefined cleanliness level may be level 4 (i.e., compliant with ISO 8 standard). In practice, the material of the partition panels and the type of connecting components are not limited thereto and may be adjusted or designed based on user requirements and production specifications.

Since the modular cleanroom can be assembled using movable partition panels, the spatial utilization efficiency within the cell factory can be improved, and the required spaces for different production schedules can be planned rapidly and flexibly according to production demands. A plurality of internal areas can be quickly assembled using multiple partition panels, thereby enhancing the overall flexibility and production efficiency of the cell factory. Furthermore, in this embodiment, the partition panels with features of rapid assembly and disassembly allow each cleanroom to function as an independent and isolated space. Accordingly, when the logistics transportation digital twin system for the modular cleanroom 1 provided by the present invention is applied to a CDMO-type cell factory, even when equipment within the factory requires yearly maintenance or servicing, the number of cleanrooms can be adjusted or relocated to different positions for yearly maintenance, servicing, or production scheduling based on the duration and condition of the equipment maintenance and repair. In addition, the layout of each cleanroom and the routing of automated vehicles in the cell factory can be adjusted in real-time according to the independence of equipment within each cleanroom or the rotation schedule of yearly maintenance. Therefore, when the cell factory faces a maintenance requirement, the logistics transportation digital twin system for the modular cleanroom 1 provided by the present invention not only prevents production stagnation caused by the shutdown of the entire factory as in conventional approaches, but also enables relocation of cleanroom modules to appropriate positions or immediate adjustment of production lines after rapid disassembly. By integrating modular cleanroom design with digital twin technology, the present invention allows for quick spatial reconfiguration based on production demands, significantly enhancing the flexibility of production scheduling and space utilization, and making the factory layout more adaptive. The system includes a built-in multi-cleanroom digital twin simulation function, which enables real-time analysis of collaborative efficiency and logistics bottlenecks among multiple cleanrooms, thereby improving coordination efficiency for concurrent multi-line production and meeting the high-demand production requirements of CDMO operations.

In one embodiment, the logistics transportation digital twin system for the modular cleanroom may include pre-installed tracks, along which the automated vehicles can transport materials. These tracks may be magnetic strips or physical rails, ensuring that the automated vehicles travel along fixed routes. In another embodiment, the automated vehicles may operate without physical tracks, utilizing technologies such as laser-guided paths, visual recognition, or internal mapping and positioning within the CDMO cell factory. This allows the automated vehicles to move freely within the factory without relying on physical tracks, thereby accommodating flexible scheduling or changes in equipment layout in the CDMO cell factory, and adapting to more complex and dynamic production environments. In this particular embodiment, integration with the digital twin module 13 enables remote control of the automated vehicle for transportation and dispatching. The system also provides real-time monitoring of each automated vehicle's operational status and power levels. This not only improves delivery efficiency but also enables the system to monitor the automated guided vehicle's transportation routes and schedules for potential errors, thereby achieving high-efficiency, high-accuracy, and automated transportation of raw materials and waste. By combining AGV intelligent scheduling and digital twin-based logistics simulation, the system can optimize transportation routes in real time, intelligently avoid overlapping or congested AGV paths, and significantly improve overall logistics scheduling efficiency, ultimately achieving a smooth and efficient production process.

In the present invention, the automatic vehicle includes an Automated Guided Vehicle (AGV), a robotic dog, and other intelligent mobile devices with autonomous navigation capabilities, such as Autonomous Mobile Robots (AMRs) or biomimetic robots with multi-legged locomotion mechanisms, to meet the logistics needs of different production environments. The automatic vehicle can autonomously select the most suitable driving mode and route according to the dispatching strategy of the logistics transportation digital twin system, to ensure efficient transportation of materials and waste. Furthermore, to cope with the corrosive environments caused by hydrogen peroxide (H₂O₂) or other acidic and alkaline chemicals commonly used in production line cleaning/disinfection operations, the structural components and housing of the automatic vehicle must be made of corrosion-resistant materials. Specifically, 316-series stainless steel exhibits excellent corrosion resistance to hydrogen peroxide with a concentration above 30% by volume, making it suitable for manufacturing the structural components and housing. Anodized aluminum alloy may also be used, as the surface oxide layer formed during the anodizing process significantly enhances corrosion resistance, making it suitable as a coating on the housing surface, thereby ensuring the long-term and stable operation of the automatic vehicle under harsh conditions.

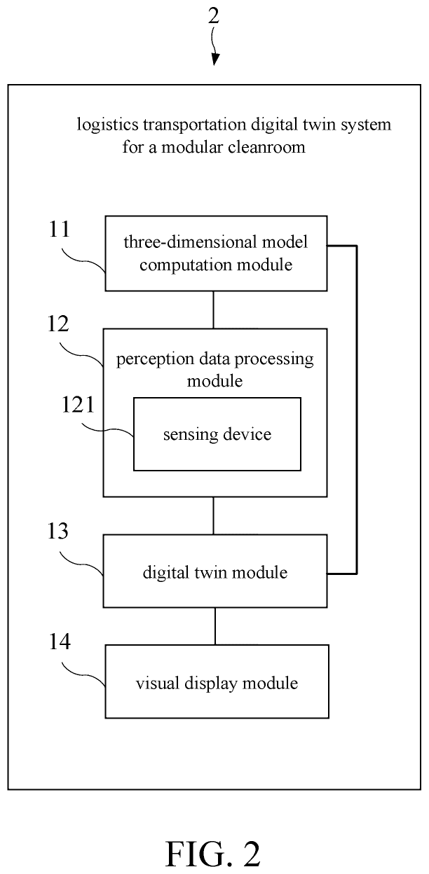

Please refer to FIG. 2, FIG. 2 shows a functional block diagram of a logistics transportation digital twin system for a modular cleanroom 2 of one embodiment of the present invention. This embodiment differs from the aforementioned embodiment in that the perception data processing module 12 in the logistics transportation digital twin system for a modular cleanroom 2 further comprises at least one sensing device 121. The sensing device 121 is configured to detect the operating status of the modular cleanroom and the automated guided vehicle. At least one sensing device is disposed on a partition panel and positioned at the junction between the internal space and the external area, so as to monitor the cleanliness of the internal space, the logistics dynamics in the external area, and the operation trajectory of the automated guided vehicle in real time. In practice, the sensing device 121 may further include one or more of the following: cameras, temperature sensors, humidity sensors, air quality sensors, particle concentration sensors, personnel and equipment tracking sensors, and sensors for detecting the position and operating status of the automated guided vehicle. These sensing devices are used to monitor images of the cleanroom, air quality, airflow velocity, temperature and humidity, equipment operation status, and logistics delivery data. It should be noted that the other modules, models, and their corresponding functions in the logistics transportation digital twin system for a modular cleanroom 2 of this embodiment are substantially the same as those described in the previous embodiment and will not be repeated herein for brevity.

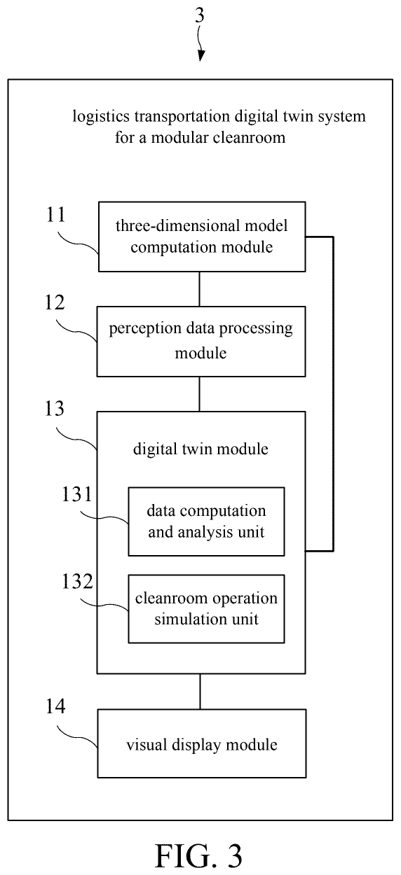

In addition to the aforementioned configurations, the logistics transportation digital twin system for a modular cleanroom 2 according to the present invention may also have other configurations. Please refer to FIG. 3, FIG. 3 shows a functional block diagram of a logistics transportation digital twin system for a modular cleanroom 3 of one embodiment of the present invention. This embodiment differs from the previous ones in that the digital twin module 13 in the logistics transportation digital twin system for the modular cleanroom 3 further comprises a data computation and analysis unit 131 and a cleanroom operation simulation unit 132. In this embodiment, the data computation and analysis unit 131 is configured to analyze the cleanroom perception data and the operational perception data, and to predict the transportation behavior of the automated guided vehicle within the modular cleanroom using machine learning models, thereby generating an optimized transportation path for the automated guided vehicle. The cleanroom operation simulation unit 132 is configured to simulate airflow dynamics within the internal space of the cleanroom, contamination diffusion paths, and automated guided vehicle transportation routes within the external areas of the cleanroom. It also uses machine learning models to optimize the transportation routes and provide the optimal path. In practice, a visual display module 14 may further provide a user interface on computers, smartphones, or tablets, allowing users to monitor and manually configure the optimized transportation routes in real time. It should be noted that the other modules, models, and their corresponding functions in the logistics transportation digital twin system for a modular cleanroom 3 of this embodiment are substantially the same as those in the previous embodiments and will not be described again for brevity.

In another embodiment, the internal space is suitable for high-cleanliness production environments, and the external area is designated for material transportation and equipment storage. The automated guided vehicle is arranged in the external area of the modular cleanroom and is configured to deliver materials or equipment into the internal space through a docking window. The automated guided vehicle further includes a body and an inner cavity. The inner cavity is arranged within the body and includes a connector corresponding to the docking window, which is used to transfer an object into the internal space through the docking window. Each docking window further comprises a first docking window and a second docking window. The object further includes a first object and a second object. The automated guided vehicle is configured to deliver the first object into the internal space through the first docking window and deliver the second object into the external area through the second docking window. The geometry of the first docking window is different from the geometry of the second docking window.

In another embodiment, when the automatic vehicle is applied in a cell factory, its inner cavity can maintain laminar airflow and positive pressure to ensure the cleanliness and safety of items (e.g., raw materials) during transportation. The inner cavity of the automatic vehicle may further be equipped with sterilization devices, such as hydrogen peroxide sterilization or ultraviolet disinfection systems, to prevent or reduce the risk of cross-contamination. Furthermore, the automatic vehicle can dock with various specialized equipment, such as Isolators, Restricted Access Barrier Systems (RABS), Biological Safety Cabinets (BSC), and Material Airlocks (MAL). Therefore, with the above-mentioned configurations, the automatic vehicle can effectively separate raw materials from waste during transportation.

Furthermore, in another embodiment, to further ensure the production environment within the cell factory, the automatic vehicle may additionally include a particle monitoring function, capable of real-time monitoring of surrounding particle levels to ensure that the cleanliness level during operation meets the required standards. The automatic vehicle system is also equipped with intelligent scheduling capabilities, which can automatically assign transportation tasks based on the equipment's power status and sterilization status of the internal chamber, thereby enhancing transportation efficiency within the cell factory.

In another embodiment, the logistics transportation digital twin system for the modular cleanroom may include a first automatic vehicle and a second automatic vehicle, wherein the two types of automatic vehicles are respectively dedicated to transporting different types of objects. For example, the first automatic vehicle is specifically used to transport a first object (such as raw materials) into the internal space through a first docking window, while the second automatic vehicle is used to transport a second object (such as waste materials) to the external area through a second docking window. The logistics transportation digital twin system for the modular cleanroom provided by the present invention can not only effectively improve the accuracy of material transportation but also significantly reduce the risk of cross-contamination.

In this embodiment, the 3D model construction module 11 is configured to establish a three-dimensional model of a modular cleanroom (not shown in the figure) and equipment (also not shown). The modular cleanroom in this embodiment may include a cleanroom (not shown), which comprises a plurality of partition panels that are configured for rapid assembly to form an interior space and an exterior region. The equipment in this embodiment may be installed within the interior space. The equipment may further include one or more of the following: a cell incubator, a cell sterile operating table, a conveyor belt, a turntable, and a robotic arm. The robotic arm may be configured to simulate human operations involved in cell culture processes (e.g., seeding, medium exchange, subculturing, and sampling), and may be precisely monitored and subjected to motion optimization through digital twin technology. However, in practice, the types of equipment are not limited to the examples mentioned above and may be selected and configured based on user requirements and the instruments needed for the production process.

In summary, the present invention provides a logistics transportation digital twin system for a modular cleanroom, which comprehensively addresses the issues in the prior art such as rigid production scheduling, difficulties in multi-cleanroom collaboration, low logistics transportation efficiency, and insufficient monitoring, thereby fully demonstrating its technical advantages and innovativeness. The present invention combines modular cleanroom design with digital twin technology to rapidly adjust spatial configurations based on production line demands, significantly enhancing the flexibility of production scheduling and the efficiency of space utilization, thereby making factory layouts more adaptable and responsive. The system features built-in digital twin simulation functions for multiple cleanrooms, allowing real-time analysis of collaborative performance and logistics bottlenecks among cleanrooms, thereby improving the efficiency of parallel production lines and meeting the demands of high-requirement manufacturing models such as CDMO. Furthermore, through intelligent AGV scheduling and digital twin-based logistics simulation, the system can optimize logistics routes in real time and intelligently avoid AGV path overlaps and congestion issues, which significantly enhances overall logistics dispatch efficiency and enables a highly efficient and streamlined production process. In addition, the invention overcomes the limitations of conventional technologies that only monitor one single production area by integrating multi-cleanroom collaboration simulation with real-time logistics scheduling, thereby achieving full-process intelligent management from production to logistics. This approach not only effectively improves production efficiency, but also significantly reduces the risk of cross-contamination and production interruptions caused by logistics bottlenecks, thereby ensuring the stability and reliability of the manufacturing process. Finally, the present invention, leveraging real-time data analysis and intelligent scheduling capabilities can rapidly respond to changing production demands and achieve decision optimization through data-driven approaches, thereby comprehensively enhancing the reliability, flexibility, and operational efficiency of the cleanroom production environment.

With the detailed description of the above embodiments, it is hoped that the features and spirit of the present invention can be more clearly described, and the scoped of the present invention is not limited by the embodiments disclosed above. On the contrary, the intention is to cover various changes and equivalent arrangements within the scope of the patents to be applied for in the present invention. Therefore, the scope of the patent application for the present invention should be interpreted broadly based on the above description so as to cover all possible changes and equivalent arrangements.

What is claimed is:

1. A logistics transportation digital twin system for a modular cleanroom, comprising:
a three-dimensional model computation module configured to construct a three-dimensional model of the modular cleanroom and an automated guided vehicle, wherein the modular cleanroom comprises a plurality of cleanrooms, and each of the cleanroom comprises a plurality of partition panels configured for rapid assembly to form an internal space and an external area;
a perception data processing module coupled to the three-dimensional model computation module, the perception data processing module configured to perceive a cleanroom parameter of the modular cleanroom to generate a cleanroom perception data, and to perceive an operational parameter of the automated guided vehicle to generate an operational perception data;
a digital twin module coupled to the three-dimensional model computation module and the perception data processing module, the digital twin module configured to perform simulation computation on the cleanroom perception data and the operational perception data with respect to the three-dimensional model to generate a three-dimensional simulation result; and
a visual display module coupled to the digital twin module, and configured to visually present the three-dimensional simulation result.

2. The logistics transportation digital twin system for the modular cleanroom of claim 1, wherein the logistics transportation digital twin system for the modular cleanroom is further integrated with a manufacturing execution system configured to monitor, track, and record a production process, and to collect and aggregate the cleanroom perception data and the operational perception data in real time, thereby managing and controlling the production process effectively.

3. The logistics transportation digital twin system for the modular cleanroom of claim 1, wherein the logistics transportation digital twin system for the modular cleanroom is applied to a cell factory, each of the partition panels is a movable panel, and the internal space of each of the cleanrooms is a sealed space maintained under positive pressure and laminar flow to achieve a predefined cleanliness level.

4. The logistics transportation digital twin system for the modular cleanroom of claim 3, wherein when the cell factory schedules a yearly maintenance, a repair and maintenance, or a production process, the cleanroom that is designated from the modular cleanrooms is reconfigured by quickly disassembling each of the movable partition panels based on the yearly maintenance, the repair and maintenance, or the production schedule, so as to comply with the yearly maintenance, the repair and maintenance, or the production schedule.

5. The logistics transportation digital twin system for the modular cleanroom of claim 3, wherein the perception data processing module further comprises:
at least one sensor configured to detect an operational state of the modular cleanroom and the automated guided vehicle, the at least one sensor disposed on one of the partition panels and positioned at a boundary between the internal space and the external area, so as to monitor in real time a cleanliness level of the internal space, a logistics activity in the external area, and an operational trajectory of the automated guided vehicle.

6. The logistics transportation digital twin system for the modular cleanroom of claim 1, wherein the digital twin module further comprises:
a data computation and analysis unit configured to analyze the cleanroom perception data and the operational perception data, and to predict a transportation behavior of the automated guided vehicle in the modular cleanroom via a machine learning model, so as to generate an optimized transportation path for the automated guided vehicle.

7. The logistics transportation digital twin system for the modular cleanroom of claim 1, wherein the digital twin module further comprises:
a cleanroom operation simulation unit configured to simulate an airflow dynamic and a contamination diffusion path of the internal space of the cleanrooms, and a transportation route of the automated guided vehicle in the external area of the cleanrooms, and to optimize the transportation route through a machine learning model to provide an optimized transportation path.

8. The logistics transportation digital twin system for the modular cleanroom of claim 1, wherein the internal space is suitable for a high-cleanliness production environment; and the external area is suitable for a material transportation zone and an equipment storage zone.

9. The logistics transportation digital twin system for the modular cleanroom of claim 8, wherein the automated guided vehicle is disposed in the external area of the modular cleanroom to deliver a material or an equipment into the internal space through a docking window, and the automated guided vehicle further comprises:
a body; and
an inner cavity disposed within the body, the inner cavity comprising a connector corresponding to the docking window for delivering an object into the internal space through the docking window.

10. The logistics transportation digital twin system for the modular cleanroom of claim 9, wherein the docking window further comprises a first docking window and a second docking window, the object further comprises a first object and a second object, and the automated guided vehicle is configured to deliver the first object into the internal space through the first docking window, and to deliver the second object into the external area through the second docking window, wherein a geometry of the first docking window is different from a geometry of the second docking window.

11. The logistics transportation digital twin system for the modular cleanroom of claim 1, wherein the cleanroom parameter further comprises one or more of a personnel parameter, an equipment parameter, a material parameter, and an environmental parameter.

12. The logistics transportation digital twin system for the modular cleanroom of claim 1, wherein the three-dimensional model computation module, the perception data processing module, the digital twin module, and the visual display module are further configured to synchronize data via a wireless communication method or a wired communication method to provide real-time operational monitoring.
